(19) United States
(12) Patent Application Publication
(10) Pub. No.: US 2019/0350093 A1
(43) Pub. Date: Nov. 14, 2019

(54) ELECTRONIC BOX FASTENING MECHANISM

(71) Applicant: DELTA ELECTRONICS, INC., Taoyuan City (TW)

(72) Inventors: Yao-Chien LIN, Taoyuan City (TW); Xin-Hung LIN, Taoyuan City (TW)

(21) Appl. No.: 16/127,679

(22) Filed: Sep. 11, 2018

(30) Foreign Application Priority Data
May 9, 2018 (CN) 201810435082.0

(51) Int. Cl. H05K 5/02; F16B 2/22; F16M 13/02

(52) U.S. Cl. CPC H05K 5/0204; H05K 5/0217; F16M 13/022; F16B 2/22

(57) ABSTRACT

An electronic box fastening mechanism includes a box body, a first hook, a second hook and a resilient hook. The box body includes a mounting surface. The first hook and the second hook are at two opposite sides of the mounting surface, and they form an installation space for receiving a guide rail. The resilient hook is at one side of the second hook. The resilient hook includes a resilient arm, a contact section and a deformation space. When pressed by the guide rail, the contact section bends toward the deformation space to allow the guide rail to be inserted in the installation space, the contact section resiliently contacts the guide rail by using an elastic restoring force of the resilient arm, and the first hook and the second hook block the guide rail, so that the guide rail is prevented from being detached from the installation space.

### TECHNICAL FIELD

The present invention relates to a fastening mechanism and, in particular, to an electronic box fastening mechanism.

### BACKGROUND

Mechanical devices or electronic devices are usually fastened to a plane by screw fastening. The mechanical devices or electronic devices have through holes, so they can be fixed to a wall or other places by screws and tools.

Alternatively, the mechanical device or the electronic device is fixed to a guide rail. The mechanical device or the electronic device is fixed to the guide rail by means of latches or movable hooks. However, users have to use tools to unfasten the screws or to apply force to the latches in order to remove the mechanical device or the electronic device from where it is fixed. Thus, it is inconvenient and time-consuming to detach the mechanical device or the electronic device.

In view of this, the inventor studied various technologies and created an effective solution in the present disclosure.

### SUMMARY

It is an objective of the present invention to provide an electronic box fastening mechanism. The present invention allows for easy installation and detachment and greatly improves convenience in use.

Accordingly, the present invention provides an electronic box fastening mechanism which is coupled to a fastener having a pair of guide rails. The electronic box fastening mechanism includes a box body, a first hook, a second hook, and a resilient hook. The box body includes a mounting surface. The first hook is disposed at one side of the mounting surface. The second hook is disposed at another side of the mounting surface opposite to the first hook. An installation space for receiving the guide rails is formed by the second hook, the first hook and the mounting surface. The installation space includes a bottom portion and a top portion adjacent to the mounting surface. The top portion is disposed opposite to the bottom portion. The resilient hook is disposed at one side of the second hook. The resilient hook includes a resilient arm connected to the box body, a contact section extended from the resilient arm, and a deformation space between the resilient arm and the contact section. When pressed by the guide rail, the contact section bends toward the deformation space to allow the guide rail to be inserted in the installation space, the contact section resiliently contacts the guide rail by using an elastic restoring force of the resilient arm, and the first hook and the second hook block the guide rail, so that the guide rail is prevented from being detached from the installation space.

Compared to conventional techniques, the electronic box fastening mechanism of the present invention has a distance between the first and second hooks, which is shorter than a distance between the guide rails, and a distance between the bottom portion and the top portion of the installation space is longer than the distance between the guide rails. When the electronic box fastening mechanism is to be coupled to the fastener, the box body is inclined to one side first, in a manner such that the guide rail can be inserted in the installation space and abutted against the resilient hook. At this point, the resilient hook pressed by the guide rail bends and deforms, so that a distance between a contact surface and the top portion of the installation space increases. Accordingly, by rotating an electronic box, the other guide rail can be rotated into the installation space. The guide rails are blocked by the first and second hooks, so the guide rails are prevented from being detached from the installation space. Installation and detachment are easy, thus greatly improving convenience in use.

### BRIEF DESCRIPTION OF THE DRAWINGS

The disclosure will become more fully understood from the detailed description and the drawings given herein below for illustration only, and thus does not limit the disclosure, wherein:

FIG. 1 is a schematic view illustrating an electronic box fastening mechanism coupled to a fastener;

FIGS. 2 and 3 are perspective exploded views illustrating the electronic box fastening mechanism and the fastener;

FIGS. 4 and 5 are schematic views illustrating operations of the electronic box fastening mechanism;

FIG. 6 is a cross-sectional view illustrating the electronic box fastening mechanism coupled to the fastener;

FIG. 7 is a partial enlarged view of FIG. 6; and

FIG. 8 is a perspective view illustrating the electronic box fastening mechanism coupled to the fastener.

### DETAILED DESCRIPTION

Detailed descriptions and technical contents of the present disclosure are illustrated below in conjunction with the accompanying drawings. However, it is to be understood that the descriptions and the accompanying drawings disclosed herein are merely illustrative and exemplary and not intended to limit the scope of the present disclosure.

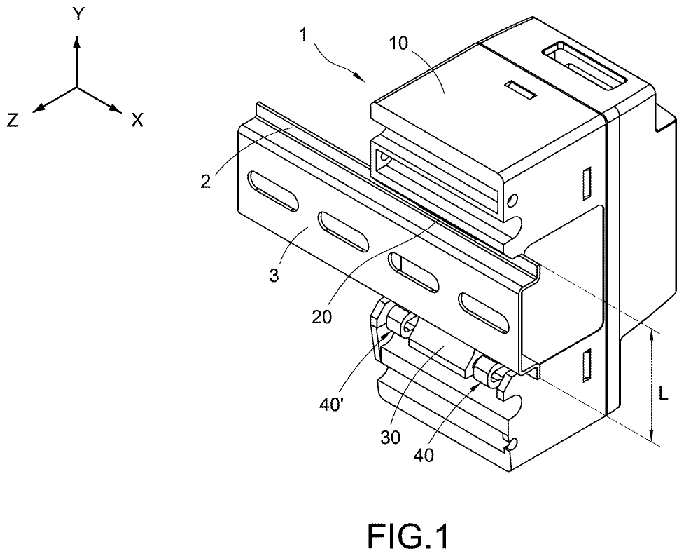

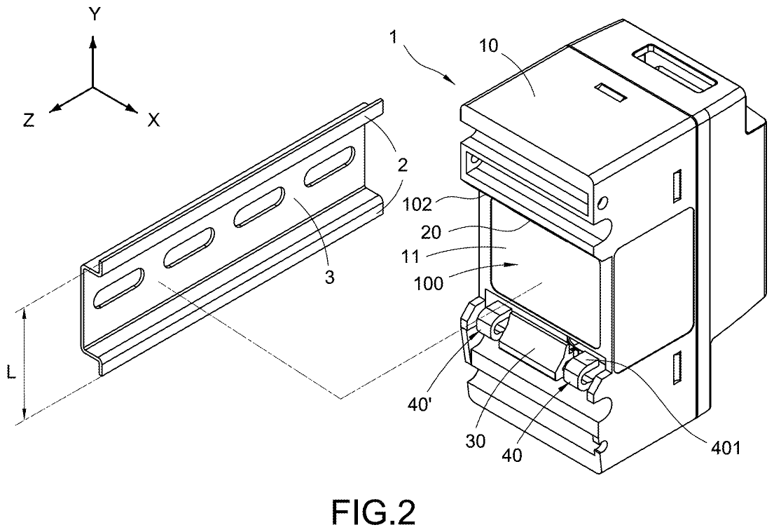

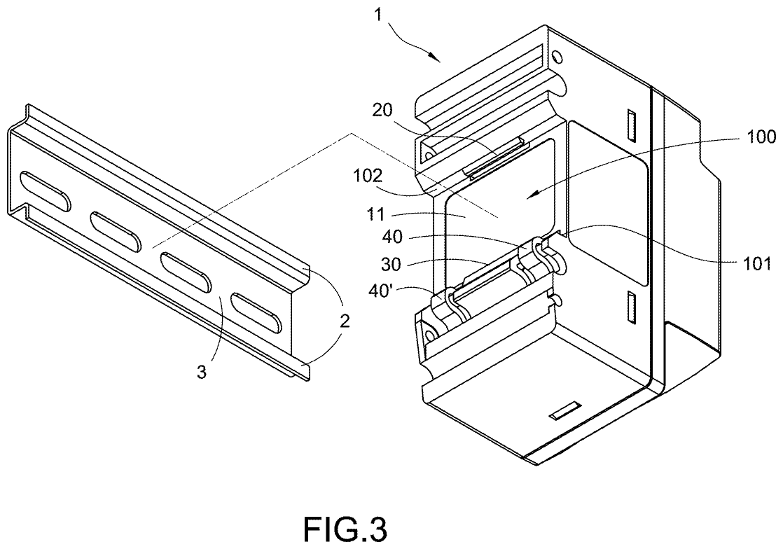

Please refer to FIG. 1 for a schematic view illustrating an electronic box fastening mechanism coupled to a fastener and also refer to FIGS. 2 and 3 for perspective exploded views taken from two different directions. The present invention provides an electronic box fastening mechanism 1 coupled to a fastener 3 having a pair of guide rails 2. The electronic box fastening mechanism 1 includes a box body 10, a first hook 20, a second hook 30, and a resilient hook 40. The first hook 20, the second hook 30 and the resilient hook 40 are all disposed on the box body 10. By using the resilient hook 40, the pair of guide rails 2 can be engaged between the first hook 20 and the second hook 30, and thereby the box body 10 can be coupled to the fastener 3. The electronic box fastening mechanism 1 is further detailed below.

The box body 10 is a housing for a mechanical device or an electronic device. The box body 10 has a mounting surface 11. In the present embodiment, the box body 10 is an electrical box; however, the present invention is not limited in this regard.

The first hook 20 is disposed at one side of the mounting surface 11. The second hook 30 is disposed at another side of the mounting surface 11 opposite to the first hook 20. In other words, the first hook 20 and the second hook 30 are disposed spaced apart from each other on the mounting surface 11. An installation space 100 for receiving the guide rails 2 is formed by the second hook 30, the first hook 20 and the mounting surface 11. The installation space 100 includes a bottom portion 101 and a top portion 102 adjacent to the mounting surface 11, the top portion 102 is disposed opposite to the bottom portion 101. Preferably, the first hook 20, the second hook 30 and the resilient hook 40 are integrally formed with the box body 10.

Referring to FIG. 1, the guide rail 2 is extended in a horizontal direction X (an X-axis direction). The pair of guide rails 2 has a guide rail interval L in a perpendicular direction Y (a Y-axis direction) perpendicular to the horizontal direction X. A Z-axis direction is perpendicular to the horizontal direction X and the perpendicular direction Y. A shortest distance in the perpendicular direction Y between the first hook 20 and the second hook 30 is shorter than the guide rail interval L.

To be specific, the electronic box fastening mechanism 1 further includes another resilient hook 40′. The two resilient hooks 40, 40′ are disposed opposite to each other at two sides of the second hook 30, respectively.

The resilient hook 40 is disposed at one side of the second hook 30. The resilient hook 40 includes a resilient arm 41 connected to the box body 10, a contact section 42 extended from the resilient arm 41, and a deformation space 400 between the resilient arm 41 and the contact section 42. When pressed by the guide rail 2, the contact section 42 bends toward the deformation space 400 to allow insertion of the guide rail 2 in the installation space 100. The contact section 42 resiliently contacts the guide rail 2 by using an elastic restoring force of the resilient arm 41, and the first hook 20 and the second hook 30 block the guide rail 2, so that the guide rail 2 is prevented from being detached from the installation space 100. It is preferable that the resilient hook 40 has a U shape.

In detail, the resilient hook 40 includes a resilient arm 41 connected to the box body 10 and a contact section 42 extended from the resilient arm 41. The contact section 42 is a free end, and a distal end of the contact section 42 is disposed adjacent to the mounting surface 11. It is preferable that, a contact surface 401 is a planar surface and is disposed at one side of the contact section 42 away from the deformation space 400.

In one embodiment of the present invention, the fastener 3 is a U-shaped fixing plate. The pair of guide rails 2 has two wing plates extended out perpendicularly from two sides of the U-shaped fixing plate.

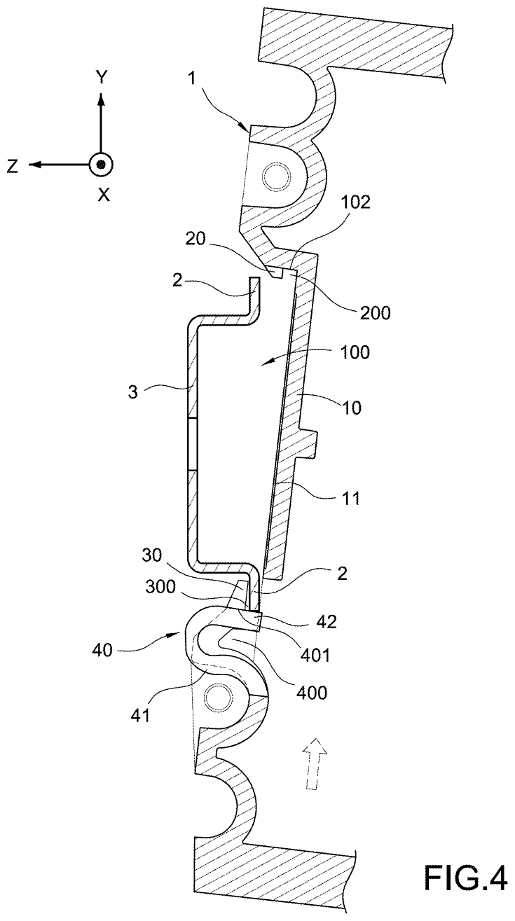

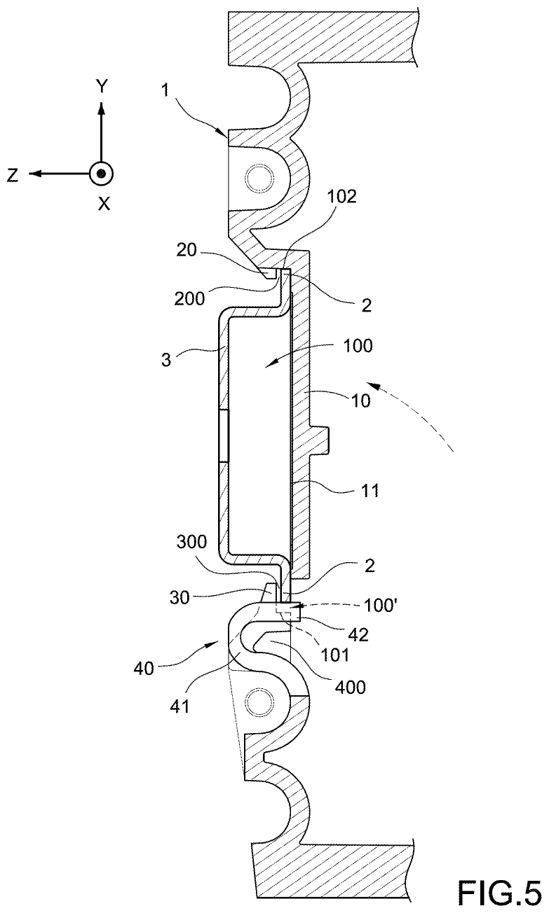

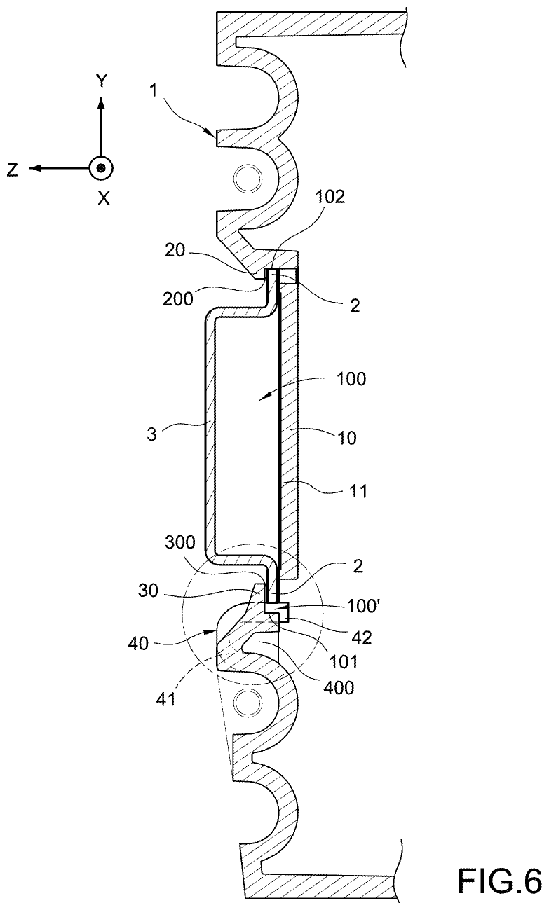

Please refer to FIGS. 4 and 5 for schematic views illustrating operations of the electronic box fastening mechanism and also refer to FIG. 6 for a cross-sectional view illustrating the electronic box fastening mechanism coupled to the fastener. As shown in the drawings, in one embodiment of the present invention, the first hook 20 and the mounting surface 11 form a first groove 200. The second hook 30 and the mounting surface 11 form a second groove 300.

It should be noted that, a distance between the first hook 20 and the second hook 30 is shorter than a distance between the two guide rails 2. A perpendicular distance in the perpendicular direction Y between the bottom portion 101 and the top portion 102 of the installation space 100 is not shorter than the perpendicular distance between the two guide rails 2. A perpendicular distance in the perpendicular direction Y between the contact surface 401 of the resilient hook 40 and the top portion 102 of the installation space 100 is substantially equal to the perpendicular distance (i.e. the guide rail interval L) between the two guide rails 2. In practice, the distance from the contact surface 401 to the top portion 102 of the installation space 100 can be slightly longer than the guide rail interval L but not longer than the distance between the first hook 20 and the second hook 30, so as to allow the box body 10 to be slidable thereon.

Referring to FIGS. 2 and 4, when the electronic box fastening mechanism 1 is to be coupled to the fastener 3, the box body 10 is inclined first, so that one side of the guide rail 2 can be inserted in the second groove 300, and the guide rail 2 is abutted against the contact surfaces 401 of the two resilient hooks 40, 40′. At this point, since the perpendicular distance in the perpendicular direction Y between the contact surface 401 and the first hook 20 is shorter than the guide rail interval L, the guide rail 2 at the other side cannot be rotated into the installation space 100.

Referring to FIG. 5, by rotating the box body 10, the contact section 42 is pressed by the guide rail 2 to bend toward the deformation space 400, so that the distance between the contact surface 401 of the resilient hook 40 and the first hook 20 is increased. As a result, the guide rail 2 can be rotated into the installation space 100 without being blocked by the first hook 20.

To be specific, when the resilient hook 40 is pressed, the perpendicular distance in the perpendicular direction Y between the contact surface 401 and the top portion 102 of the installation space 100 is increased, so that the pair of guide rails 2 can be inserted in the installation space 100. Then, by rotating the box body 10, the guide rail 2 at the other side can be rotated into the first groove 200. At this point, the contact section 42 resiliently contacts the guide rail 2 by means of an elastic restoring force of the resilient arm 41. After the guide rail 2 enters the installation space 100, the first hook 20 and the second hook 30 block the guide rail 2 to prevent it from being detached from the installation space 100 since the shortest distance in the perpendicular direction Y between the first hook 20 and the second hook 30 is shorter than the guide rail interval L.

Please refer to FIG. 6, showing the electronic box fastening mechanism 1 coupled to the fastener 3. The guide rail 2 at one side is abutted against the top portion 102 of the installation space 100, and the guide rail 2 at the other side resiliently contacts the contact surface 401 of the resilient hook 40. Moreover, the pair of guide rails 2 is blocked at their outer sides by the first hook 20 and the second hook 30. Accordingly, the box body 10 can be effectively coupled to the fastener 3.

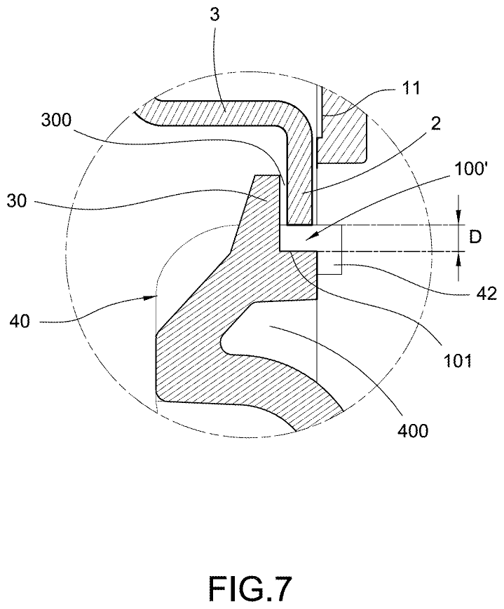

It should be noted that, the perpendicular distance in the perpendicular direction Y between the bottom portion 101 and the top portion 102 of the installation space 100 is longer than the perpendicular distance (i.e. the guide rail interval L) between the two guide rails 2. Therefore, in FIG. 7, a buffering gap D exists between the perpendicular distance of the installation space 100 and the guide rail interval L (i.e. the perpendicular distance between the two guide rails 2). Consequently, a buffering space 100′ exists when the pair of guide rails 2 is inserted in the installation space 100. The buffering space 100′ facilitates adjusting the perpendicular distance between the two guide rails 2, thus improving convenience in use.

When to detach the box body 10 from the fastener 3, a user presses the contact surface 401 of the resilient hook 40, the pair of guide rails 2 presses on the contact section 42 and moves toward the buffering space 100′. Then, by rotating the box body 10, the first hook 20 unblock the guide rail 2, and the guide rail 2 at one side can be rotated out of the installation space 100. By this way, the box body 10 can be detached from the fastener 3.

It should be noted that, the electronic box fastening mechanism 1 can be used to fasten multiple electronic boxes. In practice, multiple electronic boxes can be coupled to the fastener 3 in the above-mentioned way. Furthermore, the perpendicular distance in the perpendicular direction Y between the contact surface 401 of the resilient hook 40 and the top portion 102 of the installation space 100 is substantially equal to the guide rail interval L. Therefore, after the box body 10 is coupled to the guide rail 2 of the fastener 3, the box body 10 is slidable on the pair of guide rails 2. As a result, movement of the box body 10 after it is coupled to the fastener 3 can be realized by adjusting the guide rail interval L and the perpendicular distance in the perpendicular direction Y between the contact surface 401 of the resilient hook 40 and the top portion 102 of the installation space 100, thus improving convenience in use.

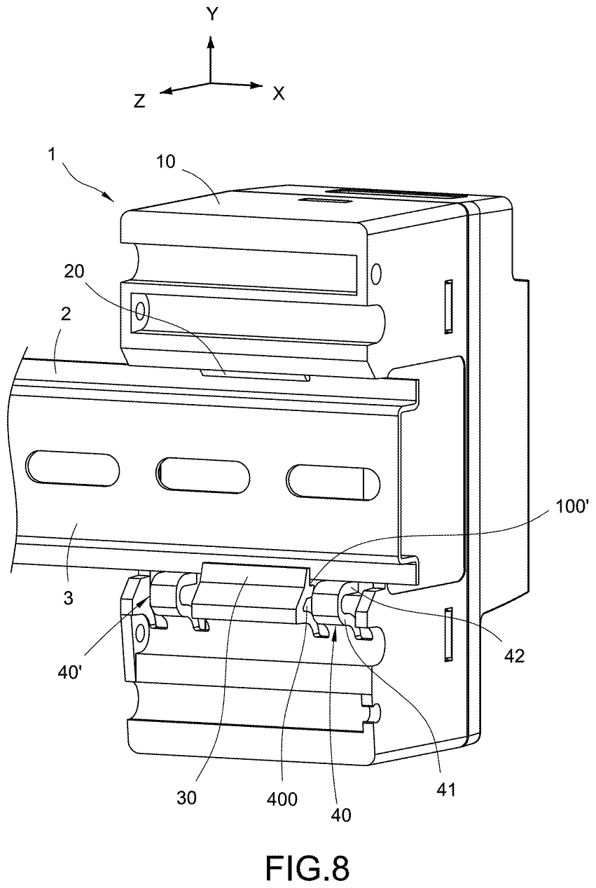

Please refer to FIG. 8 for a schematic view illustrating that the electronic box fastening mechanism is fixed to the guide rail. As shown in the drawing, in the present embodiment, the first hook 20 and the second hook 30 are disposed opposite to each other in spaced apart relationship on the mounting surface 11. Furthermore, the second hook 30 and the resilient hook 40 are disposed adjacent to each other with respect to the mounting surface 11. The guide rail 2 is extended along the horizontal direction X and disposed on the second hook 30 and the two resilient hooks 40, 40′.

It is to be understood that the above descriptions are merely the preferable embodiments of the present invention and are not intended to limit the scope of the present invention. Equivalent changes and modifications made in the spirit of the present invention are regarded as falling within the scope of the present invention.

What is claimed is:

1. An electronic box fastening mechanism, coupled to a fastener having a pair of guide rails, comprising:
a box body, the box body including a mounting surface;
a first hook disposed at one side of the mounting surface;
a second hook disposed at another side of the mounting surface opposite to the first hook, an installation space for receiving the guide rails being formed by the second hook, the first hook and the mounting surface, the installation space including a bottom portion and a top portion adjacent to the mounting surface, the top portion being disposed opposite to the bottom portion; and
a resilient hook disposed at one side of the second hook, the resilient hook including a resilient arm connected to the box body, a contact section extended from the resilient arm, and a deformation space between the resilient arm and the contact section, wherein when pressed by the guide rail, the contact section bends toward the deformation space to allow the guide rail to be inserted in the installation space, the contact section resiliently contacts the guide rail by using an elastic restoring force of the resilient arm, and the first hook and the second hook block the guide rail, so that the guide rail is prevented from being detached from the installation space.

2. The electronic box fastening mechanism according to claim 1, wherein a first groove is formed by the first hook and the mounting surface, and a second groove is formed by the second hook and the mounting surface.

3. The electronic box fastening mechanism according to claim 1, wherein the guide rail is extended in a horizontal direction, the guide rail has a guide rail interval in a perpendicular direction perpendicular to the horizontal direction, and a shortest distance between the first hook and the second hook is shorter than the guide rail interval.

4. The electronic box fastening mechanism according to claim 3, wherein a perpendicular distance in the perpendicular direction between the bottom portion and the top portion of the installation space is not shorter than the guide rail interval.

5. The electronic box fastening mechanism according to claim 3, wherein the contact section includes a contact surface, and a perpendicular distance in the perpendicular direction between the contact surface and the top portion of the installation space is equal to or longer than the guide rail interval.

6. The electronic box fastening mechanism according to claim 1, wherein the first hook, the second hook and the resilient hook are integrally formed with the box body.

7. The electronic box fastening mechanism according to claim 1, further comprising another resilient hook, the two resilient hooks being disposed opposite to each other at two sides of the second hook respectively.

8. The electronic box fastening mechanism according to claim 1, wherein the resilient hook has a U shape.

9. The electronic box fastening mechanism according to claim 5, wherein the contact surface is a planar surface and is disposed at one side of the contact section away from the deformation space.

10. The electronic box fastening mechanism according to claim 9, wherein the contact section is a free end, and a distal end of the contact section is disposed adjacent to the mounting surface.

11. The electronic box fastening mechanism according to claim 1, wherein the box body is an electrical box.

12. The electronic box fastening mechanism according to claim 3, wherein the guide rail is extended in the horizontal direction and disposed on the second hook and the resilient hook.
